(19) United States
(12) Patent Application Publication
(10) Pub. No.: US 2021/0218910 A1
(43) Pub. Date: Jul. 15, 2021

(54) IMAGE DETECTOR WITH LATERAL ELECTRONIC COLLECTION

(71) Applicant: New Imaging Technologies, Verrieres-le-Buisson (FR)

(72) Inventors: Vincent Noguier, Bourg-la-Reine (FR); Simon Ferré, Massy (FR)

(21) Appl. No.: 17/104,545

(22) Filed: Nov. 25, 2020

(30) Foreign Application Priority Data
Jan. 13, 2020 (FR) 20 00262

(51) Int. Cl. H04N 5/33; H04N 5/378

(52) U.S. Cl. CPC H04N 5/33; H04N 5/378

(57) ABSTRACT

A method for operating an image sensor including a medium having at least one photosensitive material capable of generating charges by photoelectric effect when the sensor is exposed to an incident light, and a collection electrodes in contact with the medium associated with pixel circuits. The method includes at least one electrical field that is created and includes at least one lateral component to collect the charges on at least one of the collection electrodes, allowing them to be read by the associated pixel circuit, wherein said electrical field is generated by creating at least one potential difference between said collection electrode and at least one other zone of the sensor, brought to a different potential, this other zone being situated between at least two collection electrodes.

### TECHNICAL FIELD

The present invention relates to image sensors in general, and more particularly and not exclusively to the image sensors for the visible and short wave infrared (SWIR), namely between 900 nm and 1700 nm.

### BACKGROUND

SWIR sensors are known that are based on a crystalline semiconductor material, such as InGaAs. Such a photosensitive structure is represented very schematically in FIG. 1.

The light is absorbed by the semiconductor material (InGaAs) 14, then the duly generated electrons are transmitted in each pixel of the read-out circuit 16 (“Read Out Integrated Circuit” ROIC) via electrodes in the form of metal balls 18 which also ensure the mechanical integrity of the assembly. This is the approach used most widely in the detectors on the market. The principle is identical for other wavelengths and materials (HgCdTe, InSb, etc.)

A second approach for IR imaging is to replace the semiconductor material 14 with dispersed nanocrystals (quantum dots, more commonly called “Colloidal Quantum Dots” (CQD)). That makes it possible to potentially have a less expensive manufacturing solution, and a sensitivity to other wavelengths.

A photosensitive structure operating according to this second approach is illustrated in FIG. 2. When the light is absorbed, the electrons are generated at the CQDs 19 in a polymer matrix 15. An electrical field \vec{E}, the resultant of which is directed according to the normal to the plane of the sensor, is applied by virtue of an outer metallic layer 11 deposited on the polymer matrix 15. This electrical field makes it possible to collect the electrons generated at each pixel of the read-out circuit 16, all the collection electrodes 18 associated with the pixels being at the same potential.

The application US 2016/0181325 describes an image sensor operating according to this second approach.

The problem with such an architecture is that the metallic layer absorbs and reflects a portion of the incident light, which reduces the sensitivity of the sensor and increases the manufacturing complexity.

### SUMMARY

There is therefore a need to further refine the image sensors, and notably resolve this problem.

The invention aims to resolve, according to a first of its aspects, by virtue of a method for operating an image sensor comprising a medium comprising at least one photosensitive material capable of generating charges by photoelectric effect when the sensor is exposed to an incident light, and collection electrodes in contact with said medium, associated with pixel circuits, a method in which at least one electrical field is created comprising at least one lateral component to collect said charges on at least one of said collection electrodes, allowing them to be read by the associated pixel circuit, and wherein said electrical field is generated by creating at least one potential difference between said collection electrode and at least one other zone of the sensor, brought to a different potential, this other zone being situated between at least two collection electrodes.

By virtue of the invention, notably the lateral component of the field created by the potential difference between said collection electrode and said at least one other zone of the sensor, it is possible to dispense with an outer electrode in the form of a metallic layer deposited on top of the medium comprising the photosensitive material.

The invention thus makes it possible to harvest more light and enhance the performance of the sensor, notably its sensitivity. Furthermore, the manufacturing of the sensor is thereby facilitated, because the step of deposition of the abovementioned outer layer is no longer necessary.

This other zone can notably be another collection electrode, which is not then used to collect the charges during the generation of the electrical field, or any other electrode or set of electrodes dedicated to the generation of this field.

The orientation of the lateral component of the electrical field can be changed sequentially to sequentially collect the charges on different respective collection electrodes. That makes it possible to use some of the existing collection electrodes as field electrodes, for the creation of the electrical field. Thus, it is possible, if so desired, for example to minimize the sensor development costs, to implement the invention with a conventional arrangement of collection electrodes, without having to incorporate additional field electrodes.

To change the orientation of the lateral component of the resultant electrical field, different electrodes can be subjected to different potentials sequentially. That makes it possible to reconstruct, with two partial consecutive images comprising the information obtained with only a part of the pixels, a complete image with the information originating from all the pixels. It is thus possible to obtain an equivalent resolution if the image acquisition frequency is reduced, compared to a conventional sensor in which all the collection electrodes are used for the acquisition of one and the same image.

In exemplary implementations, at least two adjacent electrodes are alternately subjected to different potentials so as to alternately collect the charges on said electrodes. This makes it possible to maximize the intensity of the field created by exploiting the proximity of the electrodes between which this field is generated.

The charges are preferentially collected on a given collection electrode using an electrical field having at least one lateral component and which is generated between the latter and at least one other electrode brought to a different potential, preferably at least two other electrodes brought to a different potential, these two other electrodes being notably equidistant from the collection electrode. That makes it possible to drain the charges present in said medium, around the collection electrodes, to the latter. In examples of implementation of the invention, at least one of these other electrodes is then used as collection electrode, the electrode having been used previously as collection electrode no longer being used as collection electrode and being used to generate the electrical field.

The collection electrodes are preferentially arranged according to a matrix arrangement, different potentials V1, V2 being, for example, applied to the electrodes according to a checkerboard arrangement, so as to generate electrical fields having at least one non-zero lateral component. Preferably, the potential of each collection electrode switches alternately from the first potential V1 to the second potential V2 and vice versa. Given that, for a pattern of potentials V1, V2 applied, only half of the pixels are active with corresponding electrodes being used to harvest the charges, and therefore to construct an image, the inversion of the checkerboard from one image to the next makes it possible to change the potentials of the electrodes of the pixels by rendering the other half of the pixels which was previously inactive active. Thus, with two nested consecutive partial images, it is possible to reconstruct a complete image with the information originating from all the pixels.

Alternatively, at least one dedicated electrode is used exclusively as field electrode to generate said electrical field, without ever being used to collect charges read by the associated pixel circuit. Thus, by virtue of these dedicated additional field electrodes, in the case where the collection electrodes are arranged according to a matrix arrangement, all the collection electrodes can be at the same potential when the pixel circuits allow it.

In this variant, all the pixels being active upon the capture of one and the same image, it is no longer necessary to subject the collection electrodes sequentially to different potentials for them to be used as field electrodes and the image produced contains the complete information for all the pixels. This solution avoids the loss of resolution upon the acquisition of an image, but can make the design of the sensor more complex by virtue of the addition of these field electrodes.

Preferably, said at least one field electrode, and, better, each field electrode, is situated between at least two collection electrodes, notably equidistant therefrom, a field having a non-zero lateral component being generated between each of these collection electrodes and the field electrode.

The field electrodes are preferentially arranged uniformly between the collection electrodes, for example so that the field electrode is surrounded by four adjacent collection electrodes. This arrangement allows for a uniform collection of charges by the collection electrodes.

Preferably, said at least one field electrode, and, better, each field electrode, has a section smaller than that of the collection electrode, when the sensor is observed from the front.

That makes it possible to not lose resolution given constant pixel matrix size.

The electrical field generated for the collection of the charges within said medium can have different time profiles, dependent, for example, on the application targeted.

The electrical field can notably be pulsed during the reading of a pixel, which can make it possible to limit the electrical consumption and the heating. In other words, when a pixel is being read, the field electrode does not keep the same potential throughout the time of reading of this pixel, and its potential exhibits, for example, at least two successive pulses.

The sensor can comprise any pixel circuits suitable for reading charges collected by the collection electrodes, and notably pixel circuits of common drain (“Source Follower”) amplifier type in linear or logarithmic mode, of column-charge amplifier type (“Capacitive Trans-Impedance Amplifier” (CTIA)) type or of direct injection type, these circuits being known in themselves and for example described in the publication “Focal-Plane-Arrays and CMOS Readout Techniques of Infrared Imaging Systems”, IEEE Transactions on circuits and systems for video technology, vol 7, No 4, August 1997.

Preferably, at least one RESET switch is mounted in parallel with the pixel circuit so as, when closed, to impose a predefined voltage on the associated electrode to allow it to generate the electrical field sought.

The reading of the pixels can be performed in global shutter mode or in rolling shutter mode.

At least one of the electrodes used to generate the electrical field with non-zero lateral component can be biased by the application of a constant voltage during the time of exposure of the corresponding pixel. The electrode which is thus biased can be the field electrode or a collection electrode used as field electrode. That can even be the collection electrode itself, when the latter is compatible with the operation of the pixel circuit, for example when the pixel circuit is of CTIA type. That can even be both, both the collection electrode and the adjacent electrode or electrodes used to create the field with the collection electrode.

This electrode can be biased before the start of the exposure time with a voltage which is the reverse of that of the biasing during the exposure time. This makes it possible to limit any charge remanence phenomenon by driving out the charges trapped in the defects.

At least one of the electrodes used to generate the electrical field with non-zero lateral component can be biased by the application of a pulsed voltage during the exposure time, as mentioned above. This makes it possible to optimize the energy consumption and reduce the heating of the sensor.

This electrode can notably be biased before the start of the exposure time and/or ceased to be biased before the end of the exposure time.

Preferably, the electrodes, notably the collection electrodes, are metallic.

The electrodes, notably the collection electrodes, can comprise one or more metals chosen from among: Al; Al/TiW; In; Au; Ti/Au; Ti/Pt/Au; Cu; Cu/Au; Ni; Ni/Au; Cr; AuSn and mixtures thereof.

The electrodes, notably the collection electrodes, preferably have a circular outline as seen from the front, notably being in the form of balls. Alternatively, the electrodes, notably the collection electrodes, are in the form of nested structures, notably in the form of combs.

The electrodes, notably the collection electrodes, are preferentially deposited on a read-out circuit of the sensor comprising the pixel circuits, before the deposition of said medium.

The electrodes, notably the collection electrodes, can be deposited by evaporation, by cathode sputtering, by machining, by electrolytic growth or by metal plating.

The electrodes, notably the collection electrodes, can be formed by a top metallic layer of a read-out circuit of the sensor comprising the pixel circuits, present at the output of the casting of the sensor, notably a top metallic layer protected or not by a passivation layer that is open at the electrodes.

The electrical field can, if necessary, exhibit a non-zero vertical component, notably generated by applying a potential difference between said collection electrode and at least one metallic layer deposited on a face of said medium, opposite that in contact with the electrodes. This can directly improve the collection of the charges generated by the incident light, even if the presence of this layer harms the sensitivity of the sensor, as in the state of the art. To preserve the sensitivity of the sensor, the medium therefore has, preferably, a face opposite that in contact with the collection electrodes which has no such metallic layer.

The photosensitive material preferably comprises nanocrystals, preferably quantum dots, notably colloidal or of graphene, dispersed in the medium.

The photosensitive material can comprise an amorphous, crystalline or semi-crystalline semiconductor.

The photosensitive material can be deposited in the form of one or more layers stacked on top of the electrodes. The photosensitive material can, as a variant, be arranged in the form of one or more layers extending in the thicknesswise direction between the electrodes.

The addition of additional layers makes it possible to optimize the performance levels by improving the transfer of the photogenerated charge carriers, or by reducing the distance that the electron-hole pairs have to travel before being dissociated. These additional layers can also allow for a multispectral operation of the sensor, for example at two different wavelengths.

The photosensitive material can also be nested and arranged in unordered fashion in said medium.

Another subject of the invention, according to another of its aspects, is an image sensor, notably for implementing the method according to the invention as defined above, comprising a medium comprising at least one photosensitive material capable of generating charges by photoelectric effect when the sensor is exposed to an incident light, and collection electrodes in contact with said medium, associated with pixel circuits, the medium having a face opposite that in contact with the collection electrodes which has no metallic layer, the pixel circuits being configured to create at least one electrical field having at least one lateral component to collect said charges on at least one of said collection electrodes.

This electrical field can notably be created between two electrodes arranged on the pixel circuits, for example between a collection electrode and adjacent collection electrodes, or between a collection electrode and one or more dedicated field electrodes, as detailed above.

The image sensor can have all or some of the features described previously.

Another subject of the invention, according to another of its aspects, is a photosensitive structure for an image sensor according to the invention, comprising:
collection electrodes, and
a medium comprising a photosensitive material capable of generating electrical charges by photoelectric effect, having a face in contact with the electrodes and an opposite face exposed to the light which has no metallic layer.

Such a medium can notably comprise nanocrystals, as mentioned above.

The structure can comprise dedicated field electrodes, as defined above.

Another subject of the invention, according to another of its aspects, is a method for manufacturing an image sensor according to the invention, comprising the deposition of said medium on the collection electrodes, this deposition being performed according to a method chosen from among: spin-coating, inkjet printing, spray-coating and drop casting.

### BRIEF DESCRIPTION OF THE DRAWINGS

The invention will be able to be better understood on reading the following detailed description, of nonlimiting examples of implementation thereof, and on studying the attached drawing, in which:

FIG. 1, previously described, schematically represents a first photosensitive structure of an image sensor of the prior art,

FIG. 2, previously described, schematically illustrates a second photosensitive structure of an image sensor of the prior art,

FIG. 3 schematically represents, by a side view, an example of a photosensitive structure according to the invention,

FIG. 4 schematically represents, by a plan view, the photosensitive structure of FIG. 3, having a matrix of electrodes with a checkerboard pattern of the potentials applied,

FIG. 5 schematically illustrates, by a plan view, a photosensitive structure according to the invention, having a matrix of electrodes with field electrodes,

FIG. 6 schematically represents an example of distribution of the RESET transistors of the pixel circuits,

FIG. 7 schematically represents, by a side view, a photosensitive structure according to the invention, with layers of semiconductor material stacked on top of the electrodes,

FIG. 8 is a schematic side view of a photosensitive structure according to the invention with layers of semiconductor material extending in the thicknesswise direction between the electrodes,

FIG. 9 is a schematic side view of a photosensitive structure according to the invention, with semiconductor material nested and arranged in unordered fashion in said medium,

FIG. 10 is a schematic side view of a photosensitive structure according to the invention, with a metallic layer deposited on a face of said medium, opposite that in contact with the electrodes,

FIG. 11a schematically represents, by a plan view, a photosensitive structure according to the invention, without the addition of electrodes,

FIG. 11b schematically illustrates, by a side view, the photosensitive structure of FIG. 11a,

FIG. 12a schematically represents, by a plan view, a photosensitive structure according to the invention, with electrodes in the form of balls,

FIG. 12b schematically illustrates, by a side view, the photosensitive structure of FIG. 12a,

FIG. 13a schematically represents, by a plan view, a photosensitive structure according to the invention with electrodes in the form of nested structures,

FIG. 13b schematically illustrates, by a side view, the photosensitive structure of FIG. 13a,

FIG. 14a is a first example of timing diagram illustrating a way of biasing the field electrode,

FIG. 14b is a second example of timing diagram illustrating another way of biasing the field electrode,

FIG. 14c is a third example of timing diagram illustrating a way of biasing the field electrode,

FIG. 14d is a fourth example of timing diagram illustrating another way of biasing the field electrode,

FIG. 14e is a fifth example of timing diagram illustrating another way of biasing the field electrode, and

FIG. 15 is a simplified diagram showing the pixel circuits and the transistors allowing the electrodes to be set to a predefined potential.

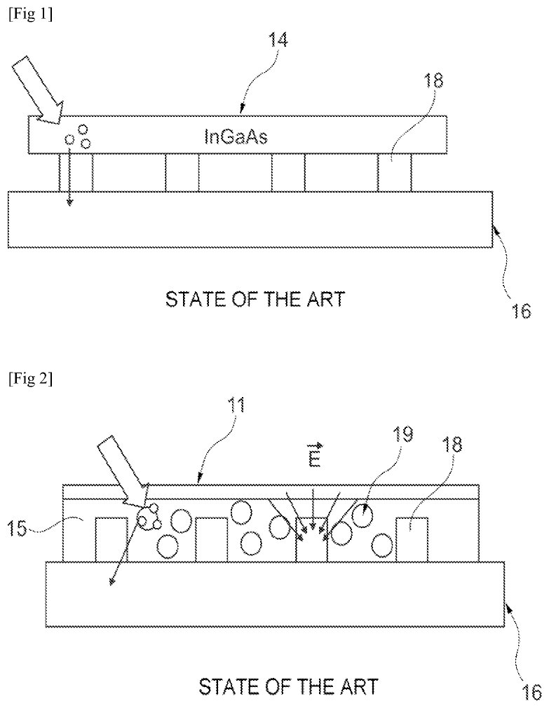

### DETAILED DESCRIPTION

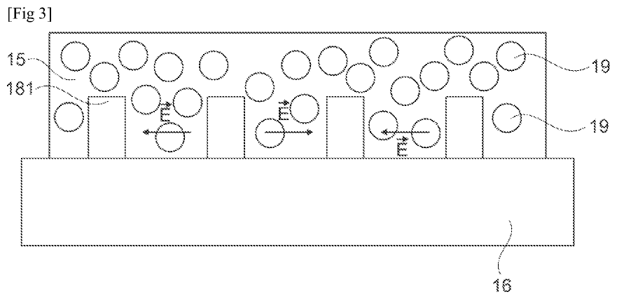

FIG. 3 schematically represents, by a side view, an example of a photosensitive structure according to the invention, comprising a read-out circuit 16 having collection electrodes 181 in contact with a medium 15 deposited on the read-out circuit 16, and comprising a photosensitive material 19.

The read-out circuit 16 is arranged to generate a potential difference between a first set 181a of said electrodes and a second set 181b of said electrodes, in order to have an electrical field \vec{E} having a non-zero lateral component to collect the charges generated in the medium by photoelectric effect, and to be able to dispense with a top metallic electrode layer, contrary to the prior art described with reference to FIG. 2.

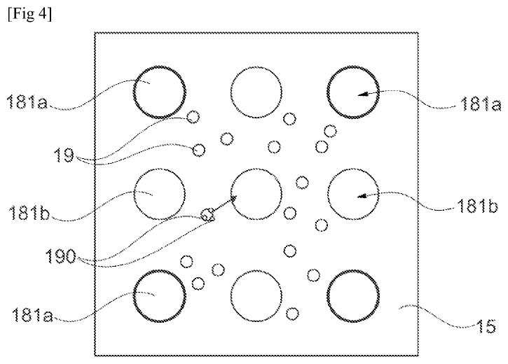

FIG. 4 schematically represents, by a plan view, the photosensitive structure of FIG. 3, in which the collection electrodes 181 are arranged into a matrix arrangement in contact with the medium 15.

The collection electrodes 181 are linked to respective pixel circuits making it possible to amplify the current collected by the latter and to thus generate an output signal representative of the lighting of the corresponding pixels.

The photosensitive material 19 is, for example, in the form of CQD dispersed in the medium 15, which comprises an electrically-insulating polymer.

To generate the electrical field sought, different potentials V1, V2 can be applied to the electrodes 181 according to a checkerboard pattern. For example, if the pixel circuits allow, the electrodes 181a are subjected at the same moment to one and the same first potential V1 while the electrodes 181b are subjected to one and the same second potential V2, different from the first.

For example, the potential difference between V1 and V2 makes it possible to generate local electrical fields in the vicinity of each collection electrode 181a, having at least one non-zero lateral component, displacing the charges generated by photoelectric effect to the latter. The charges 190 generated by photoelectric effect at the CQDs are then collected by the collection electrodes 181a. In the case where the charges 190 are electrons, the potential V1 of the electrodes 181a collecting these electrons is then greater than the potential V2 of the electrodes 181b.

In this example, only half of the collection electrodes 181, namely the electrodes 181a, is thus active at a given instant to collect the charges generated by photoelectric effect.

Therefore, to recover the missing information from the other pixels corresponding to the electrodes 181b, the potentials V1 and V2 are reversed sequentially from one image to another, that is to say that the electrodes 181a to which the potential V1 was previously applied then have the potential V2 applied, and vice versa. Then, the electrodes 181a cease to be active and the charges are collected by the electrodes 181b. Then, the electrodes 181b once again cease to be active and the charges are collected by the electrodes 181a, and so on.

Thus, it is possible to reconstruct, with two less resolved consecutive images comprising the information for only half of the pixels of the sensor, a more resolved image with the complete information for all the pixels.

Moreover, it is possible to have voltages V1 and V2 that are both positive, or both negative, or in which one is positive and the other is negative, provided that there is a sufficient potential difference to create a lateral electrical field allowing the collection of the charges.

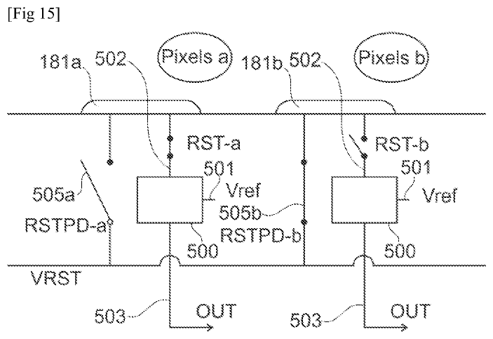

FIG. 15 schematically represents an example of a circuit making it possible to ensure the reading of the pixels and the setting of the electrodes to the desired potentials.

In this figure, the collection electrodes 181a are associated with the pixels “a” and the collection electrodes 181b are associated with the pixels “b”.

Whatever the type of architecture of the pixel circuit 500 (common drain (“Source Follower”) amplifier type in linear or logarithmic mode, column-charge (“Capacitive Trans-Impedance Amplifier” (CTIA)) amplifier type, or direct injection (DI) type, it conventionally has two inputs: a first input 501 connected to a reference voltage Vref and a second input 502 connected to the electrode 181a or 181b via an optional switch RSTa or RSTb. The output 503 of the pixel circuit is denoted “OUT”. A switch 505a (RSTPDa) or 505b (RSTPDb), consisting for example of a transistor, is mounted to bypass the pixel circuit 500 linking the electrode 181a or 181b to a voltage line of predefined potential VRST.

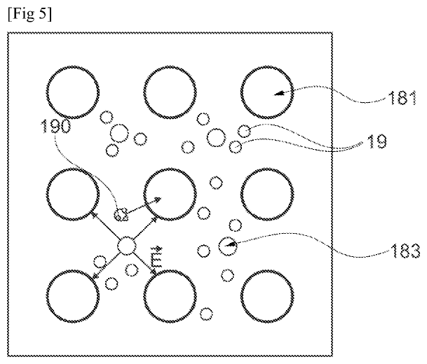

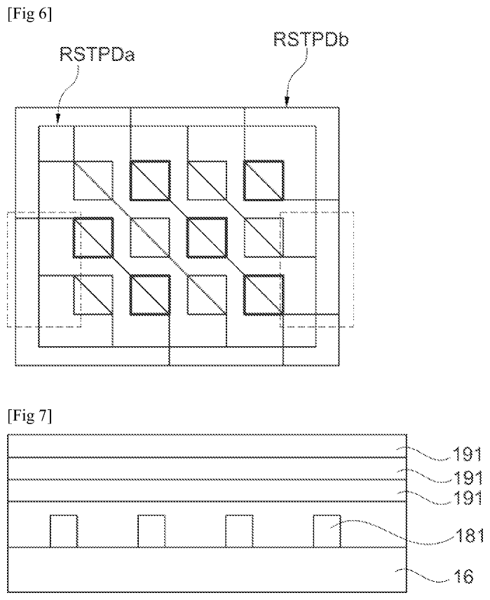

FIG. 6 illustrates, by a plan view, an example of connection of the switches 505. All the switches 505a associated with the collection electrodes 181a can be linked together by parallel connections to one and the same line RSTPDa, as illustrated in FIG. 6, while the other switches 505b associated with the collection electrodes 181b are linked to another line RSTPDb, by connections which are nested between those of the line RSTPDa.

During a first phase, the switches 505a and RST-b are open and the switches 505-b and RST-a are closed, thus bringing the electrodes 181a to a potential lower than VRST, and the electrodes 181b to a potential equal to VRST.

During this phase, the pixels b can also be reset while the pixels a are integrated, by closing the switch RST-b.

During a second phase, the switches 505-a and RST-b are closed and the switches 505-b and RST-a are open, thus bringing the electrodes 181a to a potential equal to VRST, and the electrodes 181b to a potential lower than VRST.

During this phase, the pixels a can also be reset while the pixels b are integrated, by closing the switch RST-a.

In a pixel circuit architecture 500 of CTIA type, the reference voltage Vref is fixed and the voltage at the terminals of the photodiode associated with this circuit, when the corresponding switch 505 is open, becomes VRST-Vref.

In a pixel circuit architecture 500 of “Source Follower” type, the voltage at the terminals of the photodiode is gradually stabilized to follow VRST, when the corresponding switch 505 is open.

The abovementioned phases of opening and of closing of the switches 505a and 505b, and vice versa, follow one another to form the abovementioned checkerboard pattern of the voltages applied.

In a variant, it is possible to still use just one and the same part of the electrodes 181 as active pixels, for example the electrodes 181a, the other part being used permanently as field electrodes.

In another variant, represented in FIG. 5, dedicated electrodes 183 are used as field electrodes to generate the electrical field without being used to collect charges read by the associated pixel circuits, in addition to the collection electrodes 181. The collection electrodes 181 can then, at the start of each exposure, be at one and the same potential, which is different from that applied to the field electrodes 183 during reading.

The field electrodes 183 are preferably, as illustrated, arranged uniformly between the collection electrodes 181, so that a field electrode 183 is surrounded by four adjacent collection electrodes 181. This arrangement allows for a uniform collection of charges.

As represented in this figure, the field electrodes 183 preferably have a section smaller than that of the collection electrodes, which makes it possible to not harm the resolution of the sensor by increasing the interval between the collection electrodes 181.

Various medium structures containing the photosensitive material can be used to generate the charges by photoelectric effect.

FIGS. 7 to 9 illustrate variants in which the photosensitive material is a semiconductor arranged in different ways in the insulating material.

FIG. 7 schematically represents a photosensitive structure with semiconductor layers 191 stacked on top of the collection electrodes 181 deposited on the read-out circuit 16.

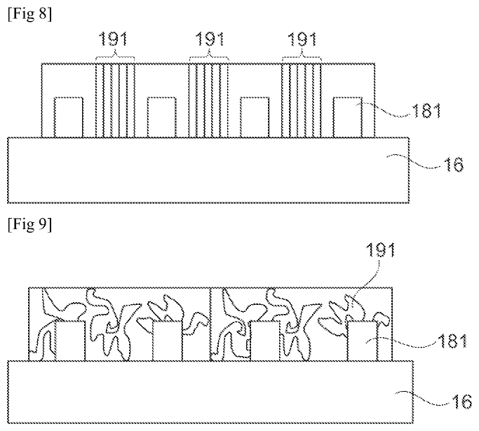

FIG. 8 illustrates a photosensitive structure with semiconductor layers 191 extending in the thicknesswise direction between the collection electrodes 181.

These semiconductor layers 191 described with respect to FIGS. 7 and 8 make it possible to optimize the performance levels by improving the transfer of the photogenerated charges, or by reducing the distance that the electron-hole pairs have to travel before being dissociated.

These additional layers can also allow for a multispectral operation of the sensor, for example at two different wavelengths.

FIG. 9 schematically represents a photosensitive structure with a semiconductor 191 that is nested and arranged in unordered fashion in the medium 15.

Although it is preferable to have a structure without top metallic electrode layer as explained above, it is nevertheless possible according to the invention to provide such a layer.

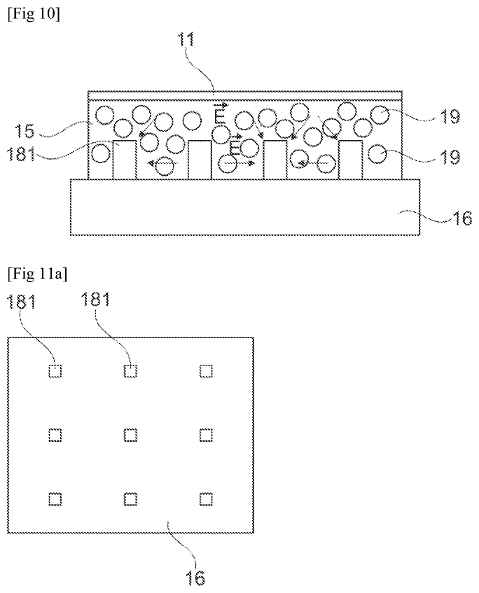

FIG. 10 represents a photosensitive structure with a metallic electrode layer 11, deposited on the face of the medium 15 opposite that in contact with the collection electrodes 181.

This electrode layer 11 is, for example, brought to a potential V2 while a part of the electrodes 181 is brought to the potential V1 to be used for the collection of the charges, and the other part is brought to the potential V2 to generate the lateral components of the field, as in the example described with reference to FIGS. 3 and 4.

In this example, the photosensitive material 19 consists of CQD dispersed in the medium 15.

The presence of the metallic layer 11 makes it possible to have an electrical field having a component normal to the surface of the medium 15, between the metallic layer 11 and the active collection electrodes. This component of the electrical field, added to the lateral component created between the adjacent electrodes, can contribute to improving the collection of the electrons.

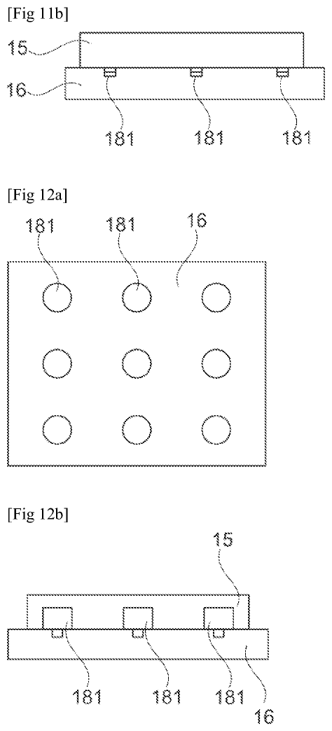

FIGS. 11a, 12a and 13a represent different examples of collection electrodes 181 suited to a photosensitive structure according to the invention.

FIGS. 11a and 11b illustrate a first variant in which the collection electrodes 181 are formed by a top metallic layer of the read-out circuit 16, present at the output of the casting of the sensor. This top metallic layer can be protected or not by a passivation layer (not represented) that is open at the collection electrodes 181.

FIGS. 12a and 12b represent a second variant in which the collection electrodes 181 are in the form of balls, having a circular outline when seen from the front.

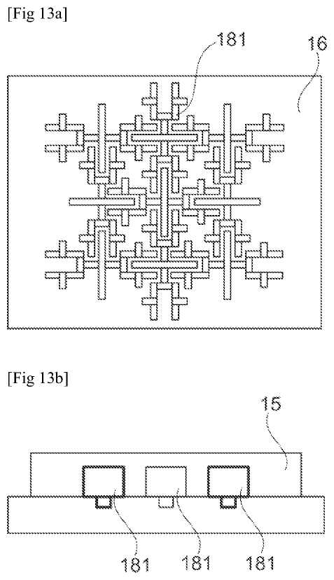

FIGS. 13a and 13b illustrate a third variant in which the collection electrodes 181 are in the form of nested structures, for example in the form of nested combs.

In the second and third variants, the electrodes are, for example, deposited by evaporation, by cathode sputtering, by machining, by electrolytic growth or by metal plating.

When the sensor comprises field electrodes, the latter can also be formed by a top metallic layer of the read-out circuit 16, by balls or blocks, or by structures in the form of combs, nested between them or with the collection electrodes. These field electrodes can be deposited by any conventional technique, for example one of those summarized above.

To the electrodes of the sensor used to generate the electrical field with non-zero lateral component, it is possible to apply various voltage profiles in time, so as to create the potential difference sought between them.

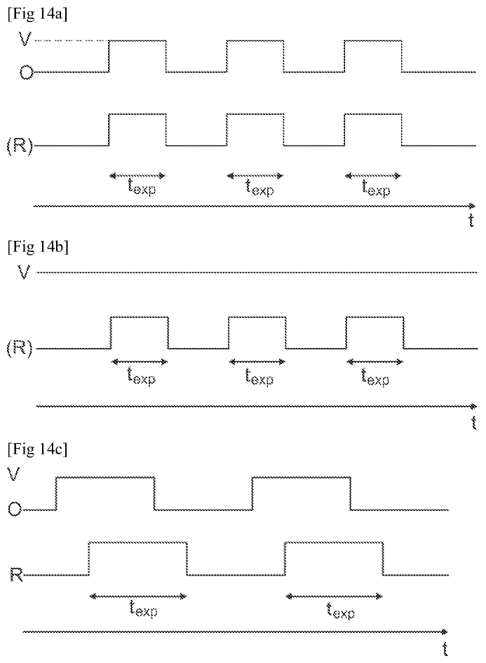

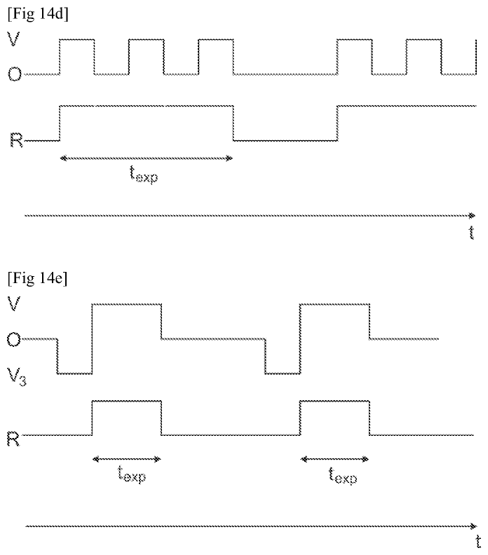

FIG. 14a presents an example of timing diagram illustrating one possibility among others for varying, in time, the bias voltage V of the field electrode, as a function of the read signal R. The read signal R makes it possible to control the exposure time. The reading of the charges takes place when the read signal R is at the high level. The time for which the high level of the signal R is maintained thus controls the exposure time.

In the example illustrated in FIG. 14a, throughout the exposure time tₑₓₚ, the field electrode is biased to a constant voltage V. As illustrated in FIG. 14b, the voltage of the field electrode is maintained constantly at V, including when the read signal R is at the low level, in order to reduce the energy consumption necessary to switchovers from the high level to the low level and vice versa.

In the example illustrated in FIG. 14c, the biasing of the field electrode to the voltage V begins just before the exposure of the associated pixel to the light and ends just before the end of the exposure.

In the example illustrated in FIG. 14d, the field electrode is biased throughout the exposure time tₑₓₚ to a voltage in the form of pulses of amplitude V. This makes it possible to reduce the energy consumption and the heating of the sensor.

In the example illustrated in FIG. 14e, the field electrode, in addition to being biased throughout the exposure time tₑₓₚ to the voltage V, is biased to a voltage of reverse sign V3 just before the start of exposure. This reduces the phenomenon of remanence of the charges by driving out the charges trapped in the defects. V3=−V for example.

The invention is not limited to the exemplary embodiments described above, or to the SWIR sensors. The invention can be used normally in mid-wavelength infrared (MWIR) or long-wavelength infrared (LWIR) sensors to detect UV radiation, notably UVC radiation, even X or gamma rays, through the use of suitable photosensitive materials.

If necessary, it is possible to allow for an option to adjust, during the use of the sensor, the time and/or amplitude profiles of the voltages applied to the field and/or collection electrodes, in order to vary the electrical field with non-zero lateral component. It is also possible to produce the sensor in such a way as to make it possible to modify, if so desired, through software for example, the potential difference V2−V1 used to generate the electrical field with lateral component, for example according to “auto-gating”, to adapt the voltage as a function of the current in order to avoid the saturation of the pixel, or the multi-pulse active imaging by driving the potential difference synchronously with a laser for a longer exposure time (e.g. FIG. 14c), or by varying the potential difference as a function of the temperature or of the exposure time to have a correction of non-uniformity that is uniform and unique.

1. A method for operating an image sensor comprising a medium comprising at least one photosensitive material capable of generating charges by photoelectric effect when the sensor is exposed to an incident light, and collection electrodes in contact with said medium, associated with pixel circuits, a method in which at least one electrical field is created comprising at least one lateral component for collecting said charges on at least one of said collection electrodes, allowing them to be read by the associated pixel circuit, wherein said electrical field is generated by creating at least one potential difference between said collection electrode and at least one other zone of the sensor, brought to a different potential, this other zone being situated between at least two collection electrodes.

2. The method according to claim 1, wherein the orientation of the lateral component of the electrical field is changed sequentially to sequentially collect the charges on different respective collection electrodes.

3. The method according to claim 1, wherein at least two adjacent electrodes are alternately subjected to different potentials so as to alternately collect the charges on said electrodes.

4. The method according to claim 2, the charges being collected on a given collection electrode using an electrical field having at least one lateral component and which is generated between the latter and at least one other electrode brought to a different potential.

5. The method according to claim 4, at least one of said other electrodes (181b) being then used as collection electrode, the electrode (181a) having been used previously as collection electrode no longer being used as collection electrode and being used to generate the electrical field.

6. The method according to claim 1, the collection electrodes being arranged according to a matrix arrangement, different potentials V1, V2 being applied to the collection electrodes according to a checkerboard arrangement, so as to generate electrical fields having at least one non-zero lateral component.

7. The method according to claim 1, wherein at least one dedicated electrode is used exclusively as field electrode to generate said electrical field without being used to collect charges read by the associated pixel circuit, a field having a non-zero lateral component being generated between each of these collection electrodes and the field electrode.

8. The method according to claim 7, the field electrode having a section smaller than that of the collection electrode.

9. The method according to claim 1, the electrical field being pulsed during the reading of a pixel.

10. The method according to claim 1, the pixel circuits being of common-drain amplifier type in linear or logarithmic mode, of column charge amplifier type or of direct injection type.

11. The method according to claim 1, at least one RESET switch is mounted in parallel with the pixel circuit so as, when closed, to impose a predefined voltage on the associated electrode.

12. The method according to claim 1, the reading of the pixels being performed in global shutter mode or in rolling shutter mode.

13. The method according to claim 1, at least one of the electrodes being biased by the application of a constant voltage during the exposure time.

14. The method according to claim 13, said electrode being biased before the start of the exposure time with a voltage which is the reverse of that of the biasing during the exposure time.

15. The method according to any one of claim 1, at least one of the electrodes being biased by the application of a pulsed voltage during the exposure time.

16. The method according to claim 13, said electrode being biased before the start of the exposure time.

17. The method according to claim 1, the electrodes being metallic.

18. The method according to claim 1, the electrodes having a circular outline when seen from the front.

19. The method according to claim 1, the electrodes being in the form of nested structures.

20. The method according to claim 1, the electrodes being deposited on a read-out circuit of the sensor, comprising the pixel circuits, before the deposition of said medium.

21. The method according to claim 20, the electrodes being deposited by evaporation, by cathode sputtering, by machining, by electrolytic growth or by metal plating.

22. The method according to claim 17, the electrodes being formed by a top metallic layer of a read-out circuit of the sensor comprising the pixel circuits, present at the output of the casting of the sensor.

23. The method according to claim 1, the electrical field also comprising a non-zero vertical component.

24. The method according to claim 1, said medium having a face opposite that in contact with the collection electrodes which has no metallic layer.

25. The method according to claim 1, the photosensitive material comprising nanocrystals dispersed in the medium.

26. The method according to claim 1, the photosensitive material comprising an amorphous, crystalline or semi-crystalline semiconductor.

27. The method according to claim 1, the photosensitive material being deposited in the form of one or more layers stacked on top of the electrodes.

28. The method according to claim 1, the photosensitive material being arranged in the form of one or more layers extending in the thicknesswise direction between the electrodes.

29. The method according to claim 1, the photosensitive material being nested and arranged in unordered fashion in said medium.

30. An image sensor comprising a medium comprising at least one photosensitive material capable of generating charges by photoelectric effect when the sensor is exposed to an incident light, and collection electrodes in contact with said medium, associated with pixel circuits, the medium having a face opposite that in contact with the collection electrodes which has no metallic layer, the pixel circuits being configured to create at least one electrical field having at least one lateral component to collect said charges on at least one of said collection electrodes.

31. A photosensitive structure for image sensor according to claim 30, comprising:
collection electrodes, and
a medium comprising a photosensitive material capable of generating electrical charges by photoelectric effect, having a face in contact with the collection electrodes and an opposite face exposed to the light which has no metallic layer.

32. A method for manufacturing an image sensor according to claim 30, comprising the deposition of the medium on the electrodes, this deposition being performed according to a method chosen from among: spin-coating, inkjet printing, spray-coating and drop-casting.
